(19) United States
(12) Patent Application Publication
(10) Pub. No.: US 2020/0111758 A1
(43) Pub. Date: Apr. 9, 2020

(54) SPILT PAD FOR PACKAGE ROUTING AND ELECTRICAL PERFORMANCE IMPROVEMENT

(71) Applicant: QUALCOMM Incorporated, San Diego, CA (US)

(72) Inventors: Aniket PATIL, San Diego, CA (US); Hong Bok WE, San Diego, CA (US); Brigham NAVAJA, San Diego, CA (US); Moshiul HAQUE, San Diego, CA (US)

(21) Appl. No.: 16/155,863

(22) Filed: Oct. 9, 2018

(51) Int. Cl. H01L 23/00

(52) U.S. Cl. CPC H01L 24/05; H01L 24/06; H01L 24/13; H01L 2224/02331; H01L 2224/02375; H01L 2224/02381; H01L 2224/13024; H01L 2224/05548; H01L 2224/05552; H01L 2224/05569; H01L 2224/06147; H01L 2224/13028; H01L 2224/0401

(57) ABSTRACT

In conventional panel level packaging, the BGA pad itself can occupy more space on the final connection layer leaving less space to route traces and vias. To address this and other issues, connection pads such as the BGA pad can be split to allow for more efficient routing on the final connection layer.

### FIELD OF DISCLOSURE

One or more aspects of the present disclosure generally relate to device packaging, and in particular, to split pad for package routing and electrical performance improvement.

### BACKGROUND

Interconnect features and design rules, such as line/space (US) and via size requirements, are getting tighter as package sizes are reduced. While helpful in decreasing the overall sizes of packages, the decreasing feature sizes come with their own issues. For example, a ball grid array (BGA) for a package can have a 0.35 mm pitch with 220 μm BGA pad, which are considerably large features compared to 10/10 μm US and 65 μm via pad. This means that each BGA pad itself can occupy more space on the final connection layer, which leaves less space to route traces and vias on this layer. This puts major restriction on the final connection layer for routing.

### SUMMARY

This summary identifies features of some example aspects, and is not an exclusive or an exhaustive description of the disclosed subject matter. Whether features or aspects are included in, or omitted from this summary is not intended as indicative of relative importance of such features. Additional features and aspects are described, and will become apparent to persons skilled in the art upon reading the following detailed description and viewing the drawings that form a part thereof.

An exemplary apparatus is disclosed. The apparatus may be selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and an automotive vehicle. The apparatus may include an inner connection layer, an outer connection layer on and above the inner connection layer, and one or more interconnects on and above the outer connection layer. The outer connection layer may include an outer substrate and an outer redistribution layer (RDL). The outer RDL may be within the outer substrate and on a top surface of the inner connection layer, and may include a plurality of split pads and one or more through-traces. First and second split pads of the plurality of split pads may be electrically coupled to a same interconnect of the one or more interconnects. At least one through-trace of the one or more through-traces may vertically overlap the same interconnect and may be laterally in between the first and second split pads.

An exemplary method is disclosed. The method may include forming an inner connection layer, forming an outer connection layer on and above the inner connection layer, and forming one or more interconnects on and above the outer connection layer. Forming the outer connection layer may include forming an outer substrate and forming an outer redistribution layer (RDL) within the outer substrate and on a top surface of the inner connection layer. The outer RDL may be formed to include a plurality of split pads and one or more through-traces. First and second split pads of the plurality of split pads may be formed so as to electrically couple to a same interconnect of the one or more interconnects. At least one through-trace of the one or more through-traces may be formed so as to vertically overlap the same interconnect and be laterally in between the first and second split pads.

Another exemplary apparatus is disclosed. The apparatus may include a die connected to a package board. The package board may include an inner connection layer, an outer connection layer on and above the inner connection layer, and one or more interconnects on and above the outer connection layer. The one or more interconnects may be electrically connected to one or more die pins of the die. The outer connection layer may include an outer substrate and an outer redistribution layer (RDL). The outer RDL, which may be within the outer substrate and on a top surface of the inner connection layer, may include a plurality of split pads and one or more through-traces. First and second split pads of the plurality of split pads may be electrically coupled to a same interconnect of the one or more interconnects. At least one through-trace of the one or more through-traces may vertically overlap the same interconnect and may be laterally in between the first and second split pads.

Yet another exemplary apparatus is disclosed. The apparatus may include an inner connection layer, an outer connection layer on and above the inner connection layer, and one or more interconnects on and above the outer connection layer. The outer connection layer may include an outer substrate and an outer redistribution layer (RDL). The outer RDL, which may be within the outer substrate and on a top surface of the inner connection layer, may include a plurality of means for providing a split connection and one or more means for providing a through-signal-connection. The plurality of means for providing the split connection may include means for providing a first split connection, and means for providing a second split connection. The means for providing the first split connection and the means for providing the second split connection may be electrically coupled to a same interconnect of the one or more interconnects. At least one of the means for providing the through-signal-connection may vertically overlap the same interconnect and may be laterally in between the first and second split pads.

### BRIEF DESCRIPTION OF THE DRAWINGS

The accompanying drawings are presented to aid in the description of examples of one or more aspects of the disclosed subject matter and are provided solely for illustration of the examples and not limitation thereof:

FIG. 1 illustrates a top view of a final connection layer of a conventional package board;

FIGS. 2A-2B illustrate top views of outer connection layers of example package boards;

FIGS. 3A-3B illustrate side views of example package boards;

FIGS. 4A-4B illustrate a physical structure of a conventional package board;

FIGS. 5A-5B illustrate a physical structure of an example package board;

FIGS. 6A-6E illustrate examples of split pad patterns;

FIG. 7 illustrates an example package;

FIG. 8A-8F illustrate stages of an example process to fabricate a package;

FIGS. 9A-9B illustrate stages of an example process to electrically couple an interconnect with split pads;

FIG. 10 illustrates a flow chart of an example method for fabricating a package;

FIG. 11 illustrates a flow chart of an example process for forming an inner connection layer;

FIG. 12 illustrates a flow chart of an example process for forming an outer connection layer and interconnects;

FIG. 13 illustrates examples of devices with packages integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer-readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

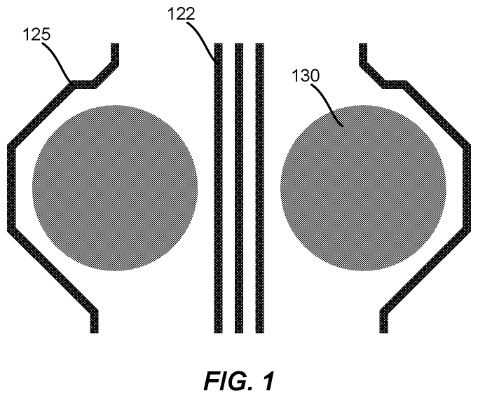

Recall that in conventional panel level packaging, the BGA pad itself can occupy more space on the final connection layer. This leaves less space to route traces and vias, and thus puts major restriction on the final connection layer for routing. FIG. 1 illustrates a top view of a final connection layer, which is the outermost connection layer, of a conventional package board, such as a printed circuit board (PCB). This outer connection layer includes pads 130 which serve as contact pads for solder balls. The outer connection layer also includes traces 122 and bent traces 125 to carry power, ground, and data signals.

The bent traces 125 are bent due to the presence of the pads 130. There are several disadvantages. As indicated above, one disadvantage is that the pad 130 can have considerably large features leaving less space to route the traces 122, 125 and vias (not shown), i.e., there can be a major restriction for routing. Another disadvantage is the bent traces 125 have increased length, which correspondingly increases signal propagation delay. Further, due to the large size of the pads 130, there can be an increase in the coupling effect.

To address one or more issues associated with the conventional package board, it is proposed to split the pad into two or more sub-pads to allow for more efficient routing on at least the final-i.e., the outermost-connection layer of a package board. It should be noted that while terms such as “upper”, “lower”, “left”, “right”, “top”, “bottom”, etc. are used in this disclosure, they should not be taken as defining absolute orientations. Rather, they should be taken simply as terms of convenience to indicate relative locations and orientations of the described components.

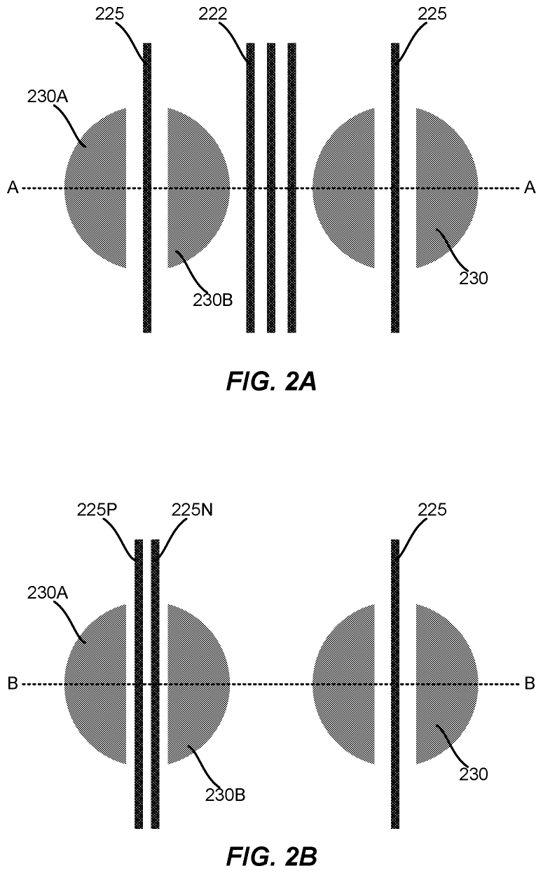

FIG. 2A illustrates a top view of a final connection layer of an example package board. A printed circuit board (PCB) may be an example of a package board. The final connection layer is the outermost layer of the package board. For convenience, the final connection layer will also be referred to as the “outer connection layer”. The outer connection layer may include any number of split pads 230, traces 222, and through-traces 225. So as to minimize clutter, not all of the split pads 230, the traces 222, and the through-traces 225 are labeled in FIG. 2A. The split pads 230, the traces 222, and the through-traces 225 may be viewed as being parts of a redistribution layer (RDL) of the outer connection layer, also referred to as “outer RDL” for convenience. The outer RDL, i.e., the split pads 230, the traces 222, and the through-traces 225, may be formed from conductive materials such as copper.

The split pads 230 may serve as contact pads for interconnects for external connection. In this way, the package board 300 may connect with other package boards and devices external to the package board. The traces 222 and the through-traces 225 may be configured to carry power, ground, and data signals. The outer connection layer may also include an outer substrate (not shown in FIG. 2A).

As will be shown further below, two or more (i.e., multiple) split pads 230 may be electrically coupled to each other. To state it another way, each split pad 230 may be electrically coupled to at least one other split pad 230. For illustration purposes, two of the split pads 230 are labeled in FIG. 2A as first and second split pad 230A, 230B. The first and second split pads 230A, 230B may be electrically coupled to each other.

One significant difference (not necessarily the only difference) between the proposed outer connection layer of FIG. 2A and the conventional final connection layer of FIG. 1 is that the outer connection layer of FIG. 2A includes the through-traces 225, which are traces that are laterally in between electrically coupled split pads 230. As seen in FIG. 2A, at least one through-trace 225 may be laterally in between the first and second split pads 230A, 230B. Also as will be shown further below, the at least one through-trace 225 may be electrically separate from the first and second split pads 230A, 230B. Unlike the bent traces 125 of the conventional final connection layer, the spacing between the first and second split pads 230A allows the through-trace 225, or at least the portion of the through-trace 225 in between the first and second split pads 230A, to be straight.

FIG. 2B illustrates a top view of another example package board. The difference between FIGS. 2A and 2B is that in FIG. 2B, there are two through-traces 225 (respectively referred to as first and second through-traces 225P, 225N) in between the first and second split pads 230A, 230B. This is simply to illustrate that there can be any number of through-traces 225 that may be in between any two electrically coupled split pads 230. While not specifically illustrated, it is contemplated that the outer connection layers of one or both of FIGS. 2A, 2B may also include bent traces 125.

The following are some (not necessarily exhaustive) of the advantages of the proposed package boards. Mechanically, the routing may be simplified as compared to the conventional final connection layer. Also, the through-traces 225 can occupy less space than the conventional bent traces 125. Further, the through-traces 225 in general can have less bends and trace length.

There are also electrical advantages. One electrical advantage is that shielding may be provided for high speed signals. For example, in FIG. 2A, the first and second split pads 230A, 230B may be grounded and the through-trace 225 in between may carry a high speed signal. Grounding the first and second split pads 230A, 230B can provide shielding so that the high speed signal may be more reliably carried on the through-trace 225. In FIG. 2B, the high speed signal may be carried by the first and second through-traces 225P, 225N as a differential signal pair. Again, grounding the first and second split pads 230A, 230B can provide shielding to the high speed differential signal pair carried on the through-traces 225P, 225N.

Another electrical advantage is that unwanted coupling effect can be reduced. Note that in an aspect, the sizes of the first and second split pads 230A, 230B combined can still be smaller than the size of a single pad 130 of the conventional final connection layer. The reduced pad sizes can effectively reduce capacitive coupling that takes place.

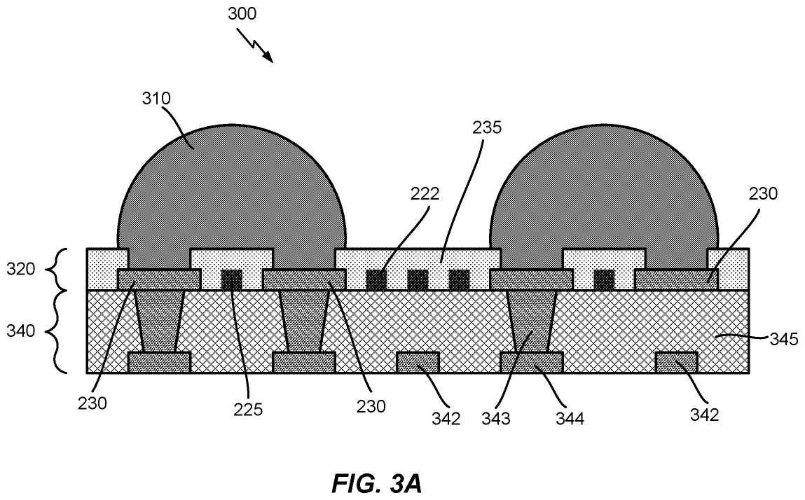

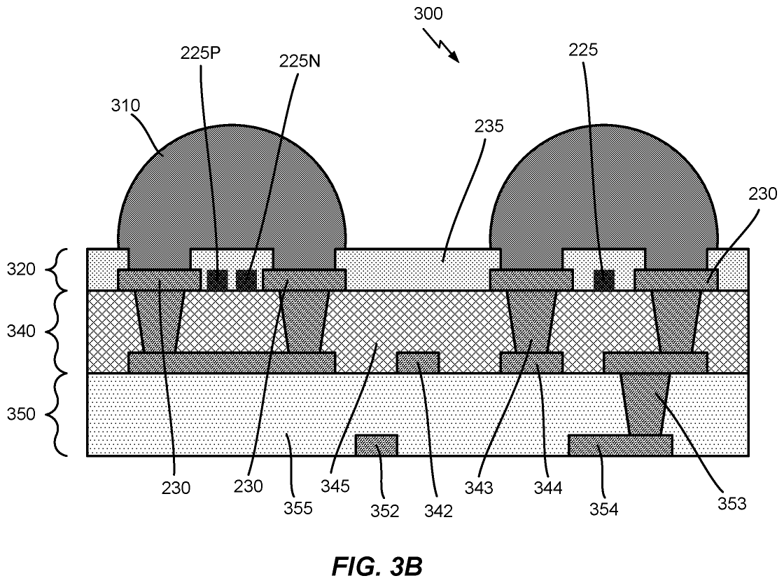

FIGS. 3A and 3B illustrate side views of example package boards 300. FIG. 3A may represent a side view taken along the line “A-A” in FIG. 2A, and FIG. 3B may represent a side view taken along the line “B-B” in FIG. 2B. As seen, the package board 300 may include an inner connection layer 340 and an outer connection layer 320 on and above the inner connection layer 340. For example, a bottom surface of the outer connection layer 320 may be in physical contact with a top surface of the inner connection layer 340. The package board 300 may also include any number of interconnects 310 on and above the outer connection layer 320.

The outer connection layer 320 may include an outer substrate 235 and an outer RDL within the outer substrate 235. The outer substrate 235 may be formed from electrically insulating materials such as dielectrics. The outer RDL may be below a top surface of the outer connection layer 320 and on the top surface of the inner connection layer 340. For example, the outer RDL may directly contact the top surface of the inner connection layer 340. The outer RDL may include any number of the split pads 230, the through-traces 225, and the traces 222. The outer RDL may be formed from conductive materials such as metal (e.g., copper).

Bottom surfaces of the outer substrate 235 and the outer RDL may together define a bottom surface of the outer connection layer 320. That is, the bottom surfaces of the outer substrate 235, the split pads 230, the through-traces 225, and the traces 222 may define the bottom surface of the outer connection layer 320. The outer RDL then may be viewed as vertically extending from the bottom surface of the outer connection layer 320 to a height below the top surface of the outer connection layer 320. In an aspect, the bottom surface of the outer connection layer 320 may be planar, i.e., the bottom surface of the outer substrate 235 may be planar with the bottom surfaces of the split pads 230, the through-traces 225, and the traces 222.

Recall from the discussion above with respect to FIGS. 2A and 2B that multiple (i.e., two or more) split pads 230 may be electrically coupled to each other. One way to accomplish this is to electrically couple the multiple split pads 230 to a common or a same interconnect 310. In FIGS. 3A and 3B, the left interconnect 310 is illustrated as being the same interconnect 310 electrically coupled to the left two split pads 230. Similarly, the right interconnect 310 is illustrated as being the same interconnect 310 electrically coupled to the right two split pads 230. Electrical coupling may be accomplished through physical contact. For example, the left interconnect 310 may be in physical contact with upper surfaces of the left two split pads 230. For ease of description, the left two split pads 230 may be referred to as the first and second split pads 230 in relation to the left interconnect 310. Similarly, the right two split pads 230 may be referred to as the first and second split pads 230 in relation to the right interconnect 310.

Also recall that the through-traces 225 may be laterally in between the electrically coupled split pads 230. This is also illustrated in FIGS. 3A and 3B. As seen, the left through-trace 225 may be laterally in between the left two split pads 230, and the right through-trace 225 may be laterally in between the right two split pads 230. More generically, the through-trace 225 may be laterally in between the first and second split pads 230. A consequence is that the left through-trace 225 may vertically overlap the left interconnect 310 and the right through-trace 225 may vertically overlap the right interconnect 310. More generically, the through-trace 225 may vertically overlap the same interconnect 310. Moreover, at least a portion of the through-trace 225 that vertically overlaps the same interconnect 310 may be straight (see FIGS. 2A, 2B).

The inner connection layer 340 may include an inner substrate 345 and an inner RDL within the inner substrate 345. The inner substrate 345 may be formed from electrically insulating materials such as dielectrics. The inner RDL may be below the top surface of the inner connection layer 340. The inner RDL may include any number of inner traces 342 and any number of inner connection pads 344. The inner RDL may be formed from conductive materials such as metal (e.g., copper).

Bottom surfaces of the inner substrate 345 and the inner RDL may together define a bottom surface of the inner connection layer 340. That is, the bottom surfaces of the inner substrate 345, the inner traces 342, and the inner connection pads 344 may define the bottom surface of the inner connection layer 340. The inner RDL then may be viewed as vertically extending from the bottom surface of the inner connection layer 340 to a height below the top surface of the inner connection layer 340. In an aspect, the bottom surface of the inner connection layer 340 may be planar, i.e., the bottom surface of the inner substrate 345 may be planar with the bottom surfaces of the inner traces 342, and the inner connection pads 344.

The inner connection layer 340 may also include any number of inner vias 343. The inner vias 343 may be formed on the inner connection pads 344 such that each inner via 343 is electrically coupled to its corresponding inner connection pad 344. For example, bottom surfaces of the inner vias 343 may be in physical contact with upper surfaces of the corresponding inner connection pads 344. The inner vias 343 may be formed from conductive materials such as metal (e.g., copper).

The inner vias 343 may also be electrically coupled to the split pads 230 of the outer connection layer 320. For example, in FIG. 3A, the three inner vias 343 are shown as being in physical contact with three of the split pads 230-to both of the first and second split pads 230 of the left interconnect 310 and to one of the first and second split pads 230 of the right interconnect 310. In FIG. 3B, the four inner vias 343 are shown as being in physical contact with all four of the split pads 230-to both of the first and second split pads 230 of the left interconnect 310 and to both of the first and second split pads 230 of the right interconnect 310.

For ease of description, the left two inner vias 343 may be referred to as first and second inner vias 343 in relation to the left interconnect 310. In this instance, it is seen that the first and second inner vias 343 are also electrically coupled to each other, e.g., at least through the left interconnect 310. If the left through-trace 225 is a high signal trace, then shielding can be provided by grounding the left interconnect 310, which in turn would ground the related first and second split pads 230, the first and second inner vias 343, and the corresponding inner connection pads 344. As seen in FIG. 3B, the first and second inner vias 343 may also be electrically coupled to each other through a common or same inner connection pad 344.

It should be noted that it is not a requirement that every split pad 230 be connected to an inner via 343. That is, each split pad 230 may or may not be physically connected to an inner via 343 intentionally based on routing preferences. For example, as seen in FIG. 3A, the right most split pad 230 is not in contact with any of the inner vias 343, i.e., for the right interconnect 310, only one of the related first and second split pads 230 is electrically coupled to its corresponding inner via 343 (e.g., through physical contact). The capability to physically connect the split pads 230 intentionally provides flexibility in routing of the inner RDL. For example, an inner trace 342, which is not electrically coupled to the right most split pad 230, may be located so as to vertically overlap the right most split pad 230.

It is contemplated that there can be any number of inner connection layers. The example package board 300 of FIG. 3A includes one inner connection layer (layer 340) and the example package board 300 of FIG. 3B includes two inner connection layers (layers 340, 350). Regarding FIG. 3B, for clarity, the term “next” will be used in reference to the inner connection layer 350.

The next inner connection layer 350 may include a next inner substrate 355 and a next inner RDL within the next inner substrate 355. The next inner substrate 355 may be formed from electrically insulating materials such as dielectrics. The next inner RDL may include any number of next inner traces 352 and any number of next inner connection pads 354. The next inner RDL may be formed from conductive materials such as metal (e.g., copper).

Bottom surfaces of the next inner substrate 355 and the next inner RDL may together define a bottom surface of the next inner connection layer 350. That is, the bottom surfaces of the next inner substrate 355, the next inner traces 352, and the next inner connection pads 354 may define the bottom surface of the next inner connection layer 350. The next inner RDL then may be viewed as vertically extending from the bottom surface of the next inner connection layer 350 to a height below the top surface of the next inner connection layer 350. In an aspect, the bottom surface of the next inner connection layer 350 may be planar, i.e., the bottom surface of the next inner substrate 355 may be planar with the bottom surfaces of the next inner traces 352, and the next inner connection pads 354.

The next inner connection layer 350 may also include any number of next inner vias 353. The next inner vias 353 may be formed on the next inner connection pads 354 such that each next inner via 353 is electrically coupled to its corresponding lower connection pad 354. For example, bottom surfaces of the next inner vias 353 may be in physical contact with top surfaces of the corresponding lower connection pads 354. The next inner vias 353 may be formed from conductive materials such as metal (e.g., copper).

The next inner vias 353 may also be electrically coupled to the inner connection pads 344 of the inner connection layer 340. For example, in FIG. 3B, the rightmost next inner via 353 is shown as being in physical contact with the rightmost inner connection pad 344. Again, whether or not a particular inner connection pad 344 is connected to a next inner via 353 may be intentionally made depending on the routing preferences.

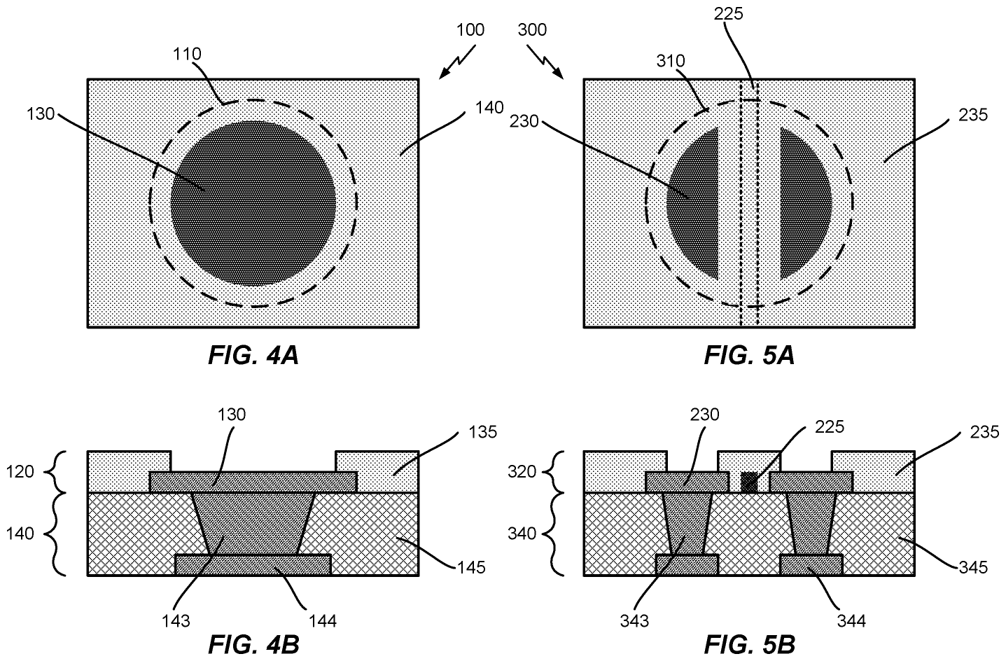

FIG. 4A-5B may be used to highlight some of the advantages of the proposed package boards relative to the conventional package boards. FIGS. 4A, 4B respectively illustrate top and side views of a conventional package board 100 and FIGS. 5A, 5B illustrate top and side views of an example package board as proposed. As seen in FIGS. 4A, 4B the conventional package board 100 includes a final connection layer 120 on an inner connection layer 120. The final connection layer 120 includes the solder pad 130 and a final substrate 135. The inner connection layer 140 includes an inner substrate 145 and an inner via 143 on an inner connection pad. In FIG. 4A, the dashed circle represents an outline of an area occupied by a solder ball 110.

As seen in FIGS. 5A, 5B, the example package board 300 may include the inner connection layer 340, the outer connection layer 320 on and above the inner connection layer 340, and one or more interconnects 310 on and above the outer connection layer 320. The outer connection layer 320 may include an outer substrate 235 and the outer RDL (split pads 230, through-traces 225, traces 222) within the outer substrate 235. The inner connection layer 340 may include the inner substrate 345, the inner RDL (inner traces 342, inner connection pads 344), and inner vias 343. In FIG. 5A, the short dashed rectangle represents an outline of a through-trace 225 within the outer substrate 235.

As mentioned, routing at the outer connection layer 320 may be made simpler and more flexible due to the through-traces 225. The through-traces 225 can occupy less space than the conventional bent traces 125, and have less bends and trace length. Electrically, shielding may be provided. Also electrically, unwanted coupling effect can be minimized due to reduction in sizes of the split pads 230, the inner vias 343, and the inner connection pads 344.

Another electrical advantage is that unwanted coupling effect can be reduced. Note that in an aspect, the size of the first and second split pads 230A, 230B combined can still be smaller than the size of a single pad 130 of the conventional final connection layer. The reduced pad sizes can effectively reduce capacitive coupling that takes place.

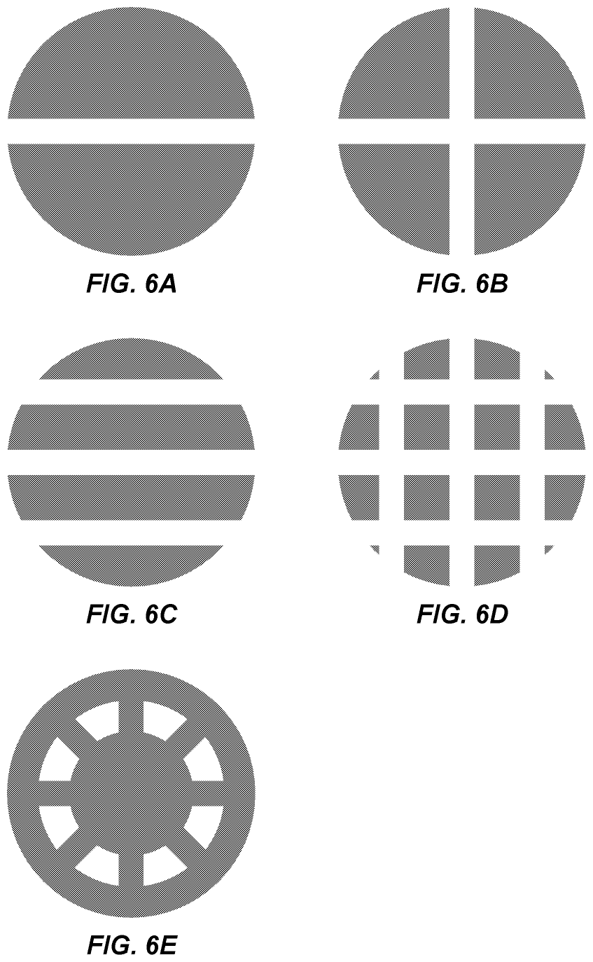

It should be noted that the split pads 230 may take on a variety of patterns as illustrated in FIGS. 6A-6E. So as to reduce clutter, the individual split pads 230 are not numbered in FIGS. 6A-6E. For each of the FIGS. 6A-6E, the split pads may be electrically coupled to each other. That is, both split pads in FIG. 6A are electrically coupled, all four split pads in FIG. 6B are electrically coupled, and so on.

While not specifically illustrated, it should be noted that any number (i.e., zero or more) through-traces 225 may be in the spacing between any two split pads. Also, the widths of the spacings need not be uniform, i.e., some spacings may be wider than others. Further, the spacings need not be limited to up/down and side/side orientations, i.e., they may be oriented in any angle. If under bump metallization (UBM) is used, then patterns like that of FIG. 6D can be used to reduce capacitance at the expense of the UBM area. Patterns like that of FIG. 6E can provide continuous UBM but with reduced metal area.

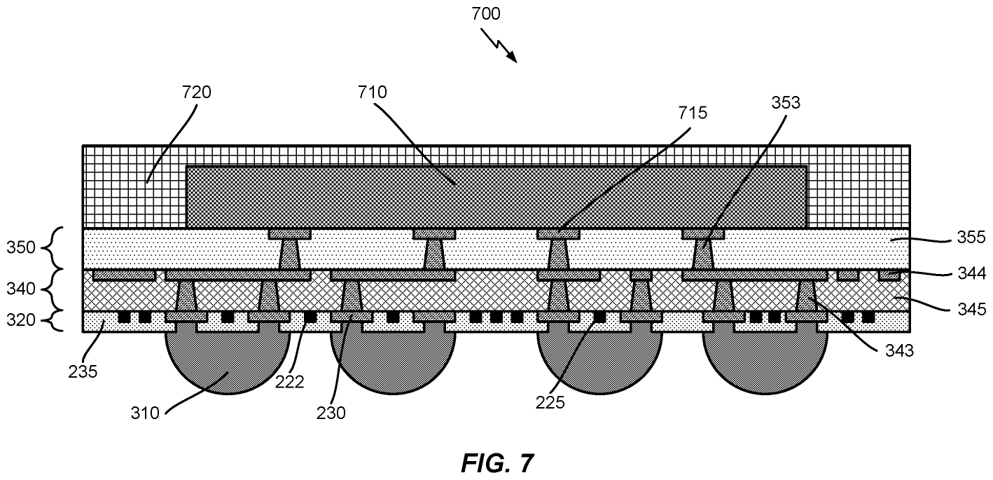

FIG. 7 illustrates an example of a package 700 that connects a die 710 to the package board 300. The package board 300 is illustrated as including the outer connection layer 320, the inner connection layer 340, and the next inner connection layer 350. While the number of inner connection layers is two in this figure, it should be noted that there can be any number of inner connection layers. As seen, the interconnects 310 may be electrically connected to die pins 715 of the die 710 through the split pads 230, the inner vias 343, the inner connection pads 344, and the next inner vias 353. In this way, access to the die 710 may be provided. The die 710 may be provided on an inner most connection layer (the next inner connection layer 350 in this instance). For protection, the die 710 may be encapsulated with a mold 720. The package 700 may be applicable to various types of packaging technology such as wafer level package (WLP), fan-out WLP (FOWLP), and so on.

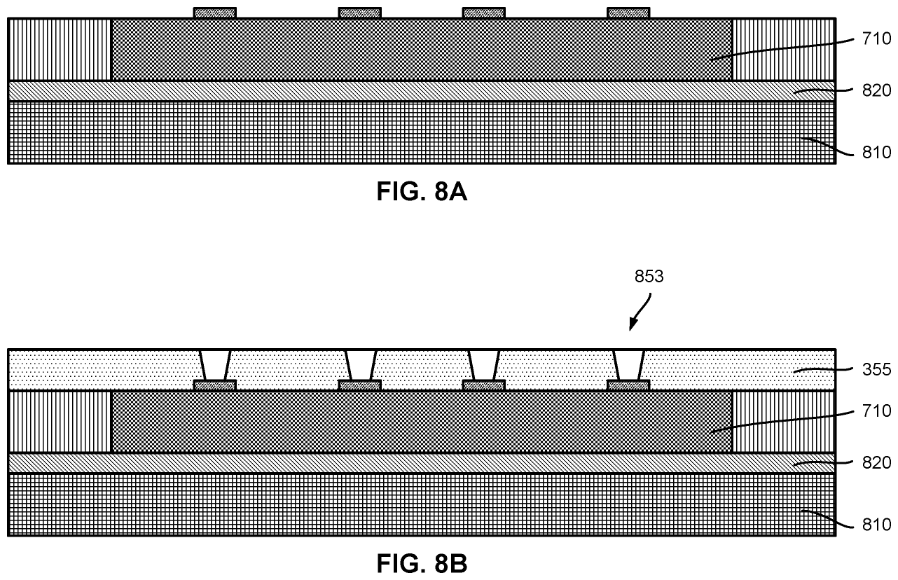

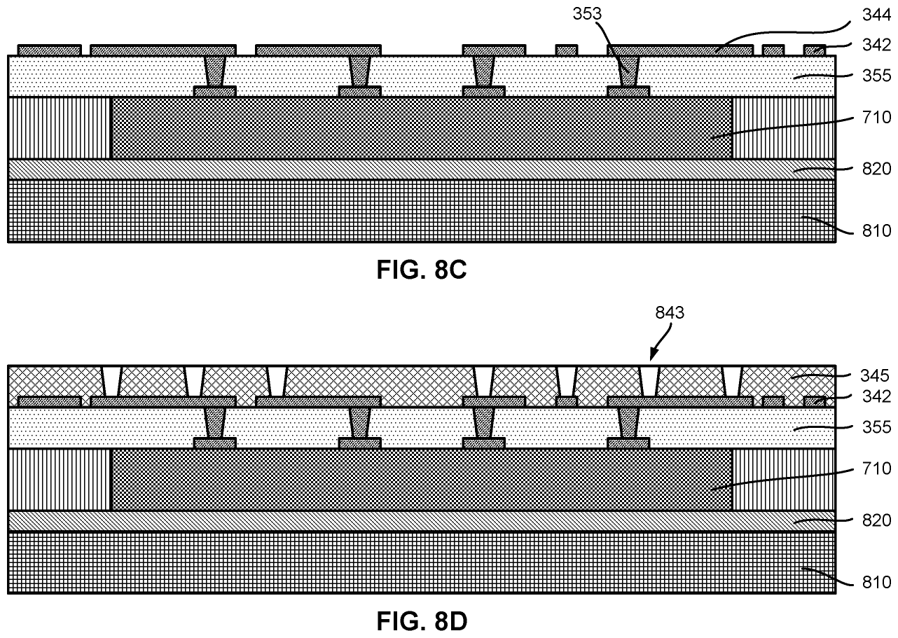

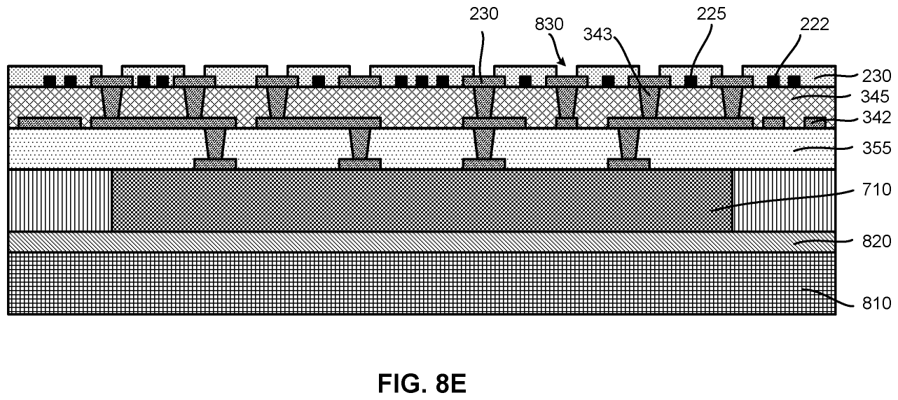

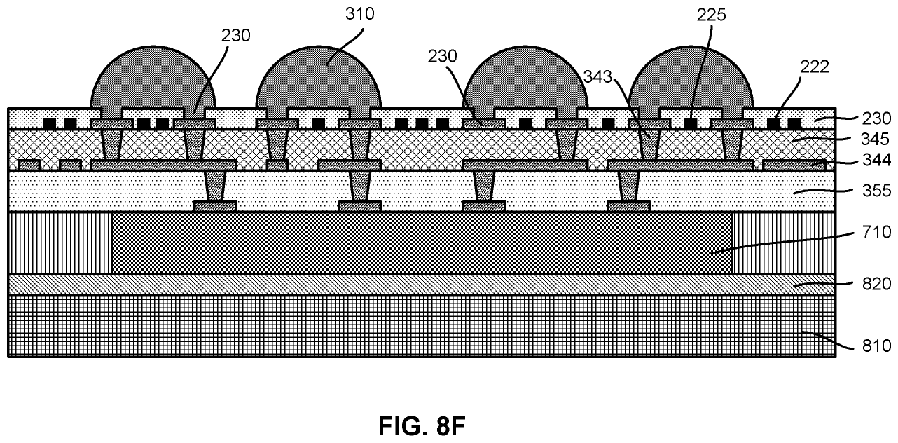

FIG. 8A-8F illustrate stages of an example process to fabricate a package such as the package 700. FIG. 8A illustrates a stage in which the die 710 may be placed on a carrier 810 on a release layer 820. FIG. 8B illustrates a stage in which a substrate, such as the next inner substrate 355, may be deposited on the die 710. The next inner substrate 355 may be etched to form next inner via holes 853 to expose the die pins 715. For example, a photoresist mask (PM) may be applied and lithography may be performed. Note that the next inner substrate 355 may also be planarized.

FIG. 8C illustrates a stage in which the conductive material such as copper may be deposited in the next inner via holes 853 to form the next inner vias 353. The conductive material may also be deposited on the upper surface of the next inner substrate 355 and etched to form the inner RDL of the inner connection layer 340, i.e., to form the inner traces 343 and the inner connection pads 344. For example, masking and lithography procedures may be used. It is seen that the next inner vias 353 of the next inner connection layer 350 and the inner connection pads 344 of the inner connection layer 340 may be formed integrally.

FIG. 8D illustrates a stage in which another substrate, such as the inner substrate 345, may be deposited on the next inner connection layer 350. The inner substrate 345 may be etched to form inner via holes 843 to expose the inner connection pads 344. For example, masking and lithography procedures may be used. The inner substrate 345 may also be planarized.

FIG. 8E illustrates a stage in which the outer connection layer 320 may be formed. For example, a conductive material such as copper may be deposited in the inner via holes 843 to form the inner vias 343. The conductive material may also be deposited on the upper surface of the inner substrate 345 and etched to form the outer RDL of the outer connection layer 320, i.e., to form the traces 222, the through-traces 225, and the split pads 230. It is then seen that the inner vias 343 of the inner connection layer 340 and the split pads 230 of the outer connection layer 320 may be formed integrally. Thereafter, the outer substrate 235 may be deposited on the upper surface of the inner connection layer 340 and on the outer RDL. Masking and lithography procedures may be used to etch the outer substrate 235 to form the split pad holes 830 to expose the split pads 230. The outer substrate 235 may also be planarized.

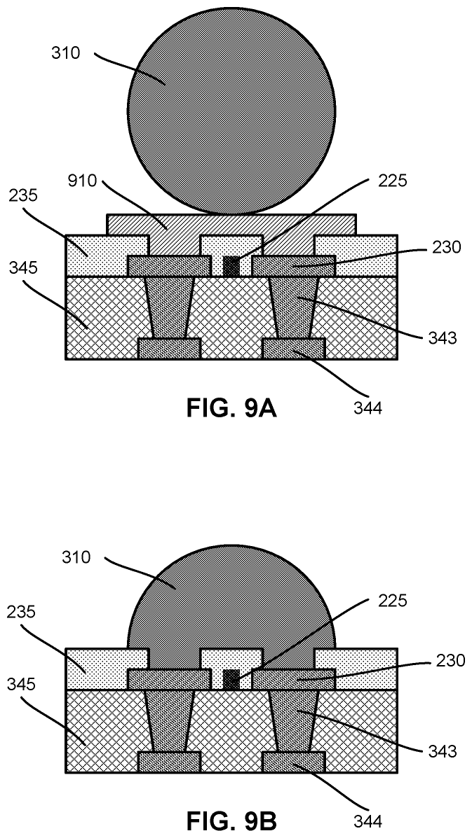

FIG. 8F illustrates a stage in which the interconnects 310 may be formed on the outer connection layer 320. In particular, the interconnects 310 may be formed to be electrically coupled to the split pads 230. FIGS. 9A, 9B illustrate stages of an example process to electrically couple an interconnect 310 with split pads 230. FIG. 9A illustrates a stage in which flux 910 is applied to over the exposed split pads 230 and over the outer substrate 235, and a solder bump (not numbered) is on the flux 910. FIG. 9B illustrates a stage after a reflow is performed.

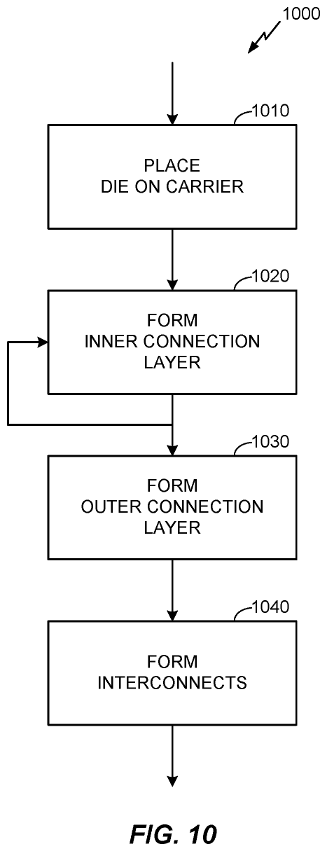

FIG. 10 illustrates a flow chart of an example method for fabricating a package such as the package 700. In block 1010, a die may be placed on a carrier. FIG. 8A may correspond to block 1010. In block 1020, an inner connection layer may be formed. Block 1020 may be repeated to form any number of inner connection layers such as the layers 340, 350 discussed above.

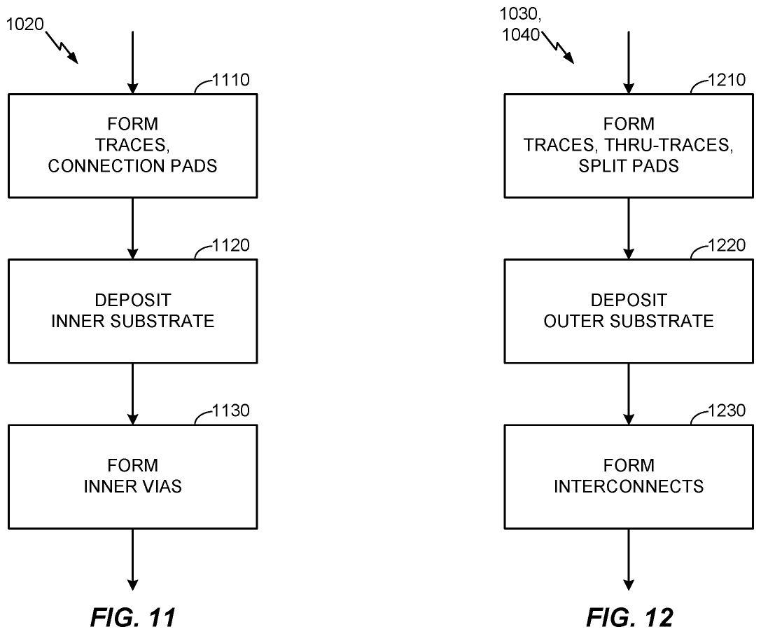

FIG. 11 illustrates a flow chart of an example process to perform block 1020. In block 1110, inner traces and inner connection pads may be formed. For example, as illustrated in FIG. 8C, the inner traces 342 and the inner connection pads 344 may be formed. In block 1120, a substrate material may be deposited to form the inner substrate. For example, as illustrated in FIG. 8B, the next inner substrate 355 may be formed. As another example illustrated in FIG. 8D, the inner substrate 345 may be formed. In block 1130, inner vias may be formed. For example, as illustrated in 8B and 8C, the next inner via holes 853 may be filled to form the next inner vias 353. Also as illustrated in FIGS. 8D and 8E, the inner via holes 843 may be filled with conductive materials (e.g., copper) to formed the inner vias 343.

Referring back to FIG. 10, in block 1030, the outer connection layer 320 may be formed. In block 1040, the interconnects 310 may be formed on the outer connection layer 320. FIG. 12 illustrates a flow chart of an example process to perform blocks 1030, 1040. In block 1210, traces 222, through-traces 225, and split pads 230 may be formed (e.g., see FIG. 8E). In block 1220, a substrate material may be deposited to form the outer substrate 235 (e.g., see FIG. 8E). In block 1230, the interconnects 310 may be formed (e.g., see FIGS. 8F, 9A, 9B).

It should be noted that not all illustrated blocks of FIGS. 10, 11, 12 need be performed, i.e., some blocks may be optional. Also, the numerical references to the blocks in these figures should not be taken as requiring that the blocks should be performed in a certain order. Indeed, some blocks may be performed concurrently.

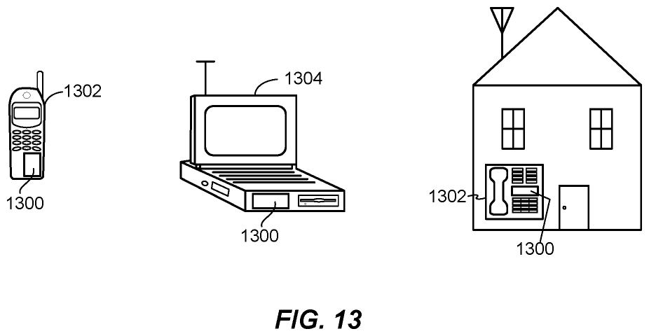

FIG. 13 illustrates various electronic devices that may be integrated with the aforementioned package board 300 and package 700. For example, a mobile phone device 1302, a laptop computer device 1304, a terminal device 1306 as well as wearable devices, portable systems, that require small form factor, extreme low profile, may include an apparatus 1300 that incorporates the object detection devices/systems as described herein. The apparatus 1300 may also be a standalone device, such as a video sensor. The devices 1302, 1304, 1306 illustrated in FIG. 13 are merely exemplary. Other electronic devices may also feature the apparatus 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the examples disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled with the processor such that the processor can read information from, and write information to, the storage medium. In the alternative, the storage medium may be integral to the processor.

Accordingly, an aspect can include a computer-readable media embodying any of the devices described above. Accordingly, the scope of the disclosed subject matter is not limited to illustrated examples and any means for performing the functionality described herein are included.

While the foregoing disclosure shows illustrative examples, it should be noted that various changes and modifications could be made herein without departing from the scope of the disclosed subject matter as defined by the appended claims. The functions, processes and/or actions of the method claims in accordance with the examples described herein need not be performed in any particular order. Furthermore, although elements of the disclosed subject matter may be described or claimed in the singular, the plural is contemplated unless limitation to the singular is explicitly stated.

What is claimed is:

1. An apparatus comprising:
an inner connection layer;
an outer connection layer on and above the inner connection layer; and
one or more interconnects on and above the outer connection layer,
wherein the outer connection layer comprises:
an outer substrate; and
an outer redistribution layer (RDL) within the outer substrate and on a top surface of the inner connection layer, the outer RDL comprising:
a plurality of split pads; and
one or more through-traces,
wherein first and second split pads of the plurality of split pads are electrically coupled to a same interconnect of the one or more interconnects, and
wherein at least one through-trace of the one or more through-traces vertically overlaps the same interconnect and is laterally in between the first and second split pads.

2. The apparatus of claim 1, wherein the at least one through-trace is electrically separate from the first and second split pads.

3. The apparatus of claim 1, wherein a portion of the at least one through-trace vertically overlapping the same interconnect is straight.

4. The apparatus of claim 1, wherein the at least one through-trace is configured to carry a high speed signal.

5. The apparatus of claim 4, wherein the at least one through-trace comprises first and second through-traces configured to carry a differential signal pair.

6. The apparatus of claim 4, wherein the same interconnect and the first and second split pads are configured to be electrically coupled to ground.

7. The apparatus of claim 1,
wherein the inner connection layer comprises:
an inner substrate;
an inner RDL within the inner substrate and below the top surface of the inner connection layer, the inner RDL comprising a plurality of inner connection pads; and
a plurality of inner vias within the inner substrate and on the plurality of inner connection pads, each inner via being electrically coupled to its corresponding inner connection pad, and
wherein first and second inner vias respectively are electrically coupled to the first and second split pads such that the first and second inner vias are electrically coupled to each other.

8. The apparatus of claim 7, wherein the first and second inner vias are electrically coupled to a same inner connection pad of the plurality of inner connection pads.

9. The apparatus of claim 1,
wherein the inner connection layer comprises:
an inner substrate;
an inner RDL within the inner substrate and below the top surface of the inner connection layer, the inner RDL comprising a plurality of inner connection pads; and
a plurality of inner vias within the inner substrate and on the plurality of inner connection pads, each inner via being electrically coupled to its corresponding inner connection pad, and
wherein one split pad of the first and second split pads is in physical contact with one inner via of the plurality of inner vias, and
wherein other split pad of the first and second split pads is not in physical contact with any of the plurality of inner vias.

10. The apparatus of claim 9,
wherein the inner RDL further comprises one or more inner traces, and
wherein the other split pad vertically overlaps at least one inner trace of the one or more inner traces without being electrically coupled to the at least one inner trace.

11. The apparatus of claim 1, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a networking device, a co-processing device, a storage device and a device in an automotive vehicle.

12. A method comprising:
forming an inner connection layer;
forming an outer connection layer on and above the inner connection layer; and
forming one or more interconnects on and above the outer connection layer,
wherein forming the outer connection layer comprises:
forming an outer substrate; and
forming an outer redistribution layer (RDL) within the outer substrate and on a top surface of the inner connection layer, the outer RDL comprising:
a plurality of split pads; and
one or more through-traces,
wherein first and second split pads of the plurality of split pads are formed so as to electrically couple to a same interconnect of the one or more interconnects, and
wherein at least one through-trace of the one or more through-traces is formed so as to vertically overlap the same interconnect and be laterally in between the first and second split pads.

13. The method of claim 12, wherein the at least one through-trace is formed to be electrically separate from the first and second split pads.

14. The method of claim 12, wherein the at least one through-trace is formed such that a portion of the at least one through-trace vertically overlapping the same interconnect is straight.

15. The method of claim 12, wherein the at least one through-trace is formed to carry a high speed signal.

16. The method of claim 15, wherein the at least one through-trace comprises first and second through-traces formed to carry a differential signal pair.

17. The method of claim 15, wherein the same interconnect and the first and second split pads are formed to be electrically coupled to ground.

18. The method of claim 12,
wherein forming the inner connection layer comprises:
forming an inner substrate;
forming an inner RDL within the inner substrate and below the top surface of the inner connection layer, the inner RDL comprising a plurality of inner connection pads; and
forming a plurality of inner vias within the inner substrate and on the plurality of inner connection pads such that each inner via is electrically coupled to its corresponding inner connection pad, and
wherein first and second inner vias respectively are formed to electrically couple to the first and second split pads such that the first and second inner vias are electrically coupled to each other.

19. The method of claim 18, wherein the first and second inner vias are formed to electrically couple to a same inner connection pad of the plurality of inner connection pads.

20. The method of claim 12,
wherein forming the inner connection layer comprises:
forming an inner substrate;
forming an inner RDL within the inner substrate and below the top surface of the inner connection layer, the inner RDL comprising a plurality of inner connection pads; and
forming a plurality of inner vias within the inner substrate and on the plurality of inner connection pads such that each inner via is electrically coupled to its corresponding inner connection pad, and
wherein one split pad of the first and second split pads is formed to be in physical contact with one inner via of the plurality of inner vias, and
wherein other split pad of the first and second split pads is formed to not be in physical contact with any of the plurality of inner vias.

21. The method of claim 20,
wherein the inner RDL is formed to further comprise one or more inner traces, and
wherein the other split pad is formed to vertically overlap at least one inner trace of the one or more inner traces without being electrically coupled with the at least one inner trace.

22. An apparatus, comprising:
a die connected to a package board, the package board comprising:
an inner connection layer;
an outer connection layer on and above the inner connection layer; and
one or more interconnects on and above the outer connection layer, the one or more interconnects being electrically connected to one or more die pins of the die,
wherein the outer connection layer comprises:
an outer substrate; and
an outer redistribution layer (RDL) within the outer substrate and on a top surface of the inner connection layer, the outer RDL comprising:
a plurality of split pads; and
one or more through-traces,
wherein first and second split pads of the plurality of split pads are electrically coupled to a same interconnect of the one or more interconnects, and
wherein at least one through-trace of the one or more through-traces vertically overlaps the same interconnect and is laterally in between the first and second split pads.

23. The apparatus of claim 22, wherein the at least one through-trace is electrically separate from the first and second split pads.

24. The apparatus of claim 22, wherein a portion of the at least one through-trace vertically overlapping the same interconnect is straight.

25. The apparatus of claim 22, wherein the at least one through-trace comprises first and second through-traces configured to carry a differential signal.

26. The apparatus of claim 22,
wherein the inner connection layer comprises:
an inner substrate;
an inner RDL within the inner substrate and below the top surface of the inner connection layer, the inner RDL comprising a plurality of inner connection pads; and
a plurality of inner vias within the inner substrate and on the plurality of inner connection pads, each inner via being electrically coupled to its corresponding inner connection pad, and
wherein first and second inner vias respectively are electrically coupled to the first and second split pads such that the first and second inner vias are electrically coupled to each other.

27. The apparatus of claim 22,
wherein the inner connection layer comprises:
an inner substrate;
an inner RDL within the inner substrate and below the top surface of the inner connection layer, the inner RDL comprising a plurality of inner connection pads; and
a plurality of inner vias within the inner substrate and on the plurality of inner connection pads, each inner via being electrically coupled to its corresponding inner connection pad, and
wherein one split pad of the first and second split pads is in physical contact with one inner via of the plurality of inner vias, and
wherein other split pad of the first and second split pads is not in physical contact with any of the plurality of inner vias.

28. An apparatus comprising:
an inner connection layer;
an outer connection layer on and above the inner connection layer; and
one or more interconnects on and above the outer connection layer,
wherein the outer connection layer comprises:
an outer substrate; and
an outer redistribution layer (RDL) within the outer substrate and on a top surface of the inner connection layer, the outer RDL comprising:
a plurality of means for providing a split connection; and
one or more means for providing a through-signal-connection, wherein the plurality of means for providing the split connection comprises:
means for providing a first split connection; and
means for providing a second split connection,
wherein the means for providing the first split connection and the means for providing the second split connection are electrically coupled to a same interconnect of the one or more interconnects, and
wherein at least one of the means for providing the through-signal-connection vertically overlaps the same interconnect and is laterally in between the means for providing the first split connection and the means for providing the second split connection.

29. The apparatus of claim 28, wherein the at least one of the means for providing the through-signal-connection is electrically separate from the means for providing the first split connection and from the means for providing the second split connection.

30. The apparatus of claim 28, wherein a portion of the at least one of the means for providing the through-signal-connection vertically overlapping the same interconnect is straight.
